(19) United States
(12) Patent Application Publication
(10) Pub. No.: US 2026/0297755 A1
(43) Pub. Date: Oct. 1, 2026

(54) ETCHANT COMPOSITION, METHOD OF PATTERNING METAL LAYER AND METHOD OF PRODUCING DISPLAY DEVICE USING THE SAME

(71) Applicants: Samsung Display Co., Ltd., Yongin-si (KR); DONGWOO FINE-CHEM Co., Ltd., Iksan-si (KR)

(72) Inventors: Shinhyuk Yang, Yongin-si (KR); Hanhee Yoon, Yongin-si (KR); Beomsoo Kim, Iksan-si (KR); Donghan Kang, Yongin-si (KR); Youngjin Yoon, Iksan-si (KR); Eunwon Lee, Iksan-si (KR); Hyeonsu Cho, Iksan-si (KR); Suckjun Lee, Iksan-si (KR)

(21) Appl. No.: 19/635,464

(22) Filed: Mar. 31, 2026

(30) Foreign Application Priority Data
Mar. 31, 2025 (KR) 10-2025-0041759

(51) Int. Cl. C23F 1/26; H10D 30/01; H10K 59/12; H10K 71/60; H10P 50/66

(52) U.S. Cl. CPC C23F 1/26; H10D 30/0314; H10P 50/667; H10K 59/1201; H10K 71/60

(57) ABSTRACT

An etchant composition includes about 3.0 wt % to about 15.0 wt % of ammonium persulfate, about 0.1 wt % to about 5.0 wt % of an inorganic acid, about 0.1 wt % to about 2.0 wt % of a fluorine-containing ammonium salt, about 0.01 wt % to about 2.0 wt % of tetraalkyl ammonium chloride, about 0.1 wt % to about 3.0 wt % of an amino group-containing sulfonic acid, about 0.1 wt % to about 5.0 wt % of an alkyl group-containing sulfonic acid, about 0.1 wt % to about 2.0 wt % of a 4-nitrogen cyclic compound (e.g., a heterocyclic compound containing four nitrogen atoms in the ring), and a remainder of water such that the total weight of the etchant composition is 100 wt %.

### CROSS-REFERENCE TO RELATED APPLICATION

The present application claims priority to and the benefit of Korean Patent Application No. 10-2025-0041759, filed on Mar. 31, 2025, in the Korean Intellectual Property Office, the entire disclosure of which is incorporated herein by reference.

### BACKGROUND

### 1. Field

One or more embodiments of the present disclosure relate to an etchant composition, a method of patterning a metal layer and a method of producing (manufacturing) a display device that utilize the etchant composition. For example, one or more embodiments of the present disclosure relate to an etchant composition, a method for patterning a metal layer utilizing the etchant composition, and a method for manufacturing a display device incorporating the patterned metal layer.

### 2. Description of the Related Art

As the field of display technologies that convey a variety of electrical signal information continues to evolve, there is increasing demand or desire for display devices that offer improved characteristics, such as reduced thickness, lighter weight, and/or lower power consumption.

With the growing resolution of display devices, precise control over the etching profiles of various conductive elements, such as wiring and electrodes, is becoming increasingly important, for example, to ensure device performance and reliability.

### SUMMARY

One or more aspects of embodiments of the present disclosure are directed toward an etchant composition capable of etching a metal multi-layer film.

Additional aspects of embodiments will be set forth in part in the description which follows and, in part, will be apparent from the description, or may be learned by practice of the presented embodiments of the disclosure.

According to one or more embodiments, an etchant composition includes
about 3.0 wt % to about 15.0 wt % of ammonium persulfate,
about 0.1 wt % to about 5.0 wt % of an inorganic acid,
about 0.1 wt % to about 2.0 wt % of a fluorine-containing ammonium salt,
about 0.01 wt % to about 2.0 wt % of tetraalkyl ammonium chloride,
about 0.1 wt % to about 3.0 wt % of an amino group-containing sulfonic acid,
about 0.1 wt % to about 5.0 wt % of an alkyl group-containing sulfonic acid,
about 0.1 wt % to about 2.0 wt % of a 4-nitrogen cyclic compound (e.g., a heterocyclic compound containing four nitrogen atoms in the ring), and
a remainder of water such that the total weight of the etchant composition is 100 wt %.

The inorganic acid may include nitric acid (HNO₃), sulfuric acid (H₂SO₄), phosphoric acid (H₃PO₄), phosphorous acid (H₃PO₃), p-toluenesulfonic acid (CH₃C₆H₄SO₃), chloric acid (HClO₃), or a (e.g., any suitable) combination thereof.

The inorganic acid may be nitric acid.

The fluorine-containing ammonium salt may include ammonium bifluoride.

The tetraalkyl ammonium chloride may include tetramethylammonium chloride, tetraethylammonium chloride, tetrapropylammonium chloride, or a (e.g., any suitable) combination thereof.

The tetraalkyl ammonium chloride may be tetramethyl ammonium chloride.

The amino group-containing sulfonic acid may include sulfamic acid, taurine, aminomethanesulfonic acid, 3-amino-1-propanesulfonic acid, or a (e.g., any suitable) combination thereof.

The amino group-containing sulfonic acid may be sulfamic acid.

The alkyl group-containing sulfonic acid may include methanesulfonic acid, ethanesulfonic acid, propanesulfonic acid, or a (e.g., any suitable) combination thereof.

The alkyl group-containing sulfonic acid may be methanesulfonic acid.

The 4-nitrogen cyclic compound may include 5-aminotetrazole, 5-methyltetrazole, 1-methyl-5-aminotetrazole, 1-ethyl-5-aminotetrazole, 5-mercapto-1-methyltetrazole, 5-methoxy-1H-tetrazole, 1H-tetrazole, or a (e.g., any suitable) combination thereof.

In one or more embodiments, the etchant composition may be to etch a metal film, a metal oxide film, a metal nitride film, or a (e.g., any suitable) combination thereof.

According to one or more embodiments,
a method of patterning a metal layer includes
providing a substrate,
forming a metal layer on the substrate,
forming a photoresist pattern on the metal layer, and
patterning the metal layer by etching the metal layer with the etchant composition as described in one or more embodiments.

The metal layer may be a multi-layer.

The metal layer may include (e.g., consist of) a metal, a metal oxide, a metal nitride, or a (e.g., any suitable) combination thereof.

In one or more embodiments, the metal may include copper, titanium, a titanium alloy, or a (e.g., any suitable) combination thereof,

and the titanium alloy may include titanium, and molybdenum (Mo), tantalum (Ta), chromium (Cr), nickel (Ni), neodymium (Nd), or a (e.g., any suitable) combination thereof.

The metal oxide may include an oxide of indium (In), tin (Sn), gallium (Ga), zinc (Zn), or a (e.g., any suitable) combination thereof.

The metal oxide may be indium tin oxide.

The metal nitride may include titanium nitride, tantalum nitride, or a (e.g., any suitable) combination thereof.

In one or more embodiments, the metal layer may include a first metal layer and a second metal layer,
wherein the first metal layer may include titanium or a titanium alloy,
the titanium alloy may include titanium, and Mo, Ta, Cr, Ni, Nd, or a (e.g., any suitable) combination thereof,
and the second metal layer may include copper.

In one or more embodiments, the metal layer may further include a metal oxide layer on the second metal layer, and the metal oxide layer may include indium tin oxide.

According to one or more embodiments,
a method of producing or manufacturing a display device, wherein the display device includes a thin-film transistor including a semiconductor layer, a gate electrode, an optional bottom metal layer beneath the semiconductor layer, and a source/drain electrode, and a light-emitting element electrically connected to the source/drain electrode, includes
providing a substrate,
forming a metal layer on the substrate,
forming a photoresist pattern on the metal layer, and
etching the metal layer with the etchant composition as described in one or more embodiments to form a metal layer pattern (e.g., a patterned metal layer),
wherein the metal layer pattern may constitute the gate electrode or the source/drain electrode.

For example, the ability of the etchant composition to selectively etch metal multi-layer structures, including combinations of metals, metal oxides, and metal nitrides, enables precise formation of conductive (e.g., electrically conductive) patterns for thin-film transistor (TFT) architectures. For example, the etchant composition facilitates the definition of gate electrodes and source/drain electrodes with high fidelity, which is desired for achieving uniform (e.g., substantially uniform) electrical performance across the display panel. The compatibility of the etchant with materials, such as titanium, copper, and/or indium tin oxide (ITO), ensures that the resulting metal layer patterns may be integrated into one or more suitable display devices, including active matrix organic light-emitting diode (AMOLED) and liquid crystal display (LCD) devices. Thus, the disclosed etchant composition and methods provide a scalable solution for advanced display device fabrication.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a plan view schematically illustrating a display device according to one or more embodiments;

FIG. 2 is a cross-sectional view schematically illustrating a portion of the display device of FIG. 1;

FIG. 3 is a schematic diagram illustrating a method of measuring side etching;

FIG. 4 is cross-sectional scanning electron microscope (SEM) images of test substrates 1 (Ti/Cu) and 2 (Ti/Cu/ITO) etched utilizing an etchant composition of Example 2;

FIG. 5 is cross-sectional SEM images of test substrates 1 (Ti/Cu) and 2 (Ti/Cu/ITO) etched utilizing an etchant composition of Comparative Example 1; and

FIG. 6 is cross-sectional SEM images of test substrates 1 (Ti/Cu) and 2 (Ti/Cu/ITO) etched utilizing an etchant composition of Comparative Example 2.

### DETAILED DESCRIPTION

Reference will be made in more detail to one or more embodiments, examples of which are illustrated in the accompanying drawings, wherein like reference numerals refer to like elements throughout the attached drawings and the written description, and duplicative descriptions thereof may not be provided in the specification. In this regard, the subject matter of the present disclosure may be embodied in different forms and should not be construed as being limited to one or more embodiments set forth herein. Rather, these embodiments are provided as examples, by referring to the drawings, to explain the aspects and features of the present disclosure to those skilled in the art.

The utilization of “may” if (e.g., when) describing embodiments of the present disclosure refers to “one or more embodiments of the present disclosure.”

In the context of the present application and unless otherwise defined, the terms “use,” “using,” and “used” may be considered synonymous with the terms “utilize,” “utilizing,” and “utilized,” respectively.

As used herein, the term “and/or” includes any and all combinations of one or more of the associated listed items.

Throughout the disclosure, the expression “at least one of a, b, or c” indicates only a, only b, only c, both (e.g., simultaneously) a and b, both (e.g., simultaneously) a and c, both (e.g., simultaneously) b and c, all of a, b, and c, or variations thereof.

Because the present disclosure may be modified in one or more suitable ways and may have one or more embodiments, certain embodiments will be illustrated in the accompanying drawings and described in more detail in the written description. The aspects, effects, and embodiments of the present disclosure and methods of achieving them will be clarified with reference to one or more embodiments and the accompanying drawings described below in more detail. However, the present disclosure is not limited to the disclosed embodiments and may be implemented in one or more suitable forms.

The terms “first,” “second,” and/or the like are not intended to be limiting, however are used to distinguish one component from another component.

The singular expression includes the plural unless the context clearly indicates otherwise.

The terms “includes,” “has,” “including,” “having,” and/or the like are intended to imply the presence of the recited features or components and do not preclude the possibility of the addition of one or more other features or components. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein is inclusive of the stated value and refers to as being within an acceptable range of deviation for the particular value as determined by one of ordinary skill in the art, considering the measurement in question and the error associated with measurement of the particular quantity (e.g., the limitations of the measurement system). For example, “about” may refer to as being within one or more standard deviations or within ±30%, ±20%, ±10%, or ±5% of the stated value. Also, it should be understood that, even if (e.g., when) the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

If (e.g., when) a portion of a film, an area, a component, and/or the like is said to be “over” or “on” the upper portion of another portion, this includes not only if (e.g., when) it is directly on the upper portion of another portion, however also if (e.g., when) there are other films, areas, components, and/or the like present therebetween. In contrast, if (e.g., when) a portion of a film, an area, a component, and/or the like is said to be “directly over” or “directly on” the upper portion of another portion, there are no other films, areas, components, and/or the like present therebetween.

In the context of the present disclosure and unless otherwise defined, plan view is an orthographic projection of a three-dimensional object from the position of a horizontal plane that intersects the object. For example, it is a top-down view, showing the layout and spatial relationships of one or more elements within the object or structure. A plan view based on a z-axis (thickness) direction refers to a top-down view of the object, as if (e.g., when) looking directly down onto the surface from above. In this context, the z-axis direction is perpendicular or normal to the horizontal plane defined by x-axis and y-axis directions.

In the drawings, components may be exaggerated or reduced in size for ease of illustration. For example, the size and thickness of each configuration or arrangement shown in the drawings may be arbitrary for ease of description, and embodiments of the present disclosure are not necessarily limited to those shown.

### Etchant Composition

According to one or more embodiments, provided is an etchant composition, including:
about 3.0 wt % to about 15.0 wt % of ammonium persulfate;
about 0.1 wt % to about 5.0 wt % of an inorganic acid;
about 0.1 wt % to about 2.0 wt % of a fluorine-containing ammonium salt;
about 0.01 wt % to about 2.0 wt % of tetraalkyl ammonium chloride;
about 0.1 wt % to about 3.0 wt % of an amino group-containing sulfonic acid;
about 0.1 wt % to about 5.0 wt % of an alkyl group-containing sulfonic acid;
about 0.1 wt % to about 2.0 wt % of a 4-nitrogen cyclic compound (e.g., a heterocyclic compound containing four nitrogen atoms in the ring); and
a remainder of water such that the total weight of the etchant composition is 100 wt %.

The wt % of the components as described in one or more embodiments represent values relative to the total weight of the etchant composition.

The ammonium persulfate may be the main or predominant oxidizing agent for copper, e.g., the main or predominant component of copper etching, and may control the etching rate. The ammonium persulfate may oxidize copper into copper ions (Cu²⁺) to enable etching.

The ammonium persulfate may be included in an amount range of about 3.0 wt % to about 15.0 wt % based on the total of 100 wt % of the etchant composition. If (e.g., when) the ammonium persulfate is included in an amount less than about 3.0 wt %, etching may not occur or the etching rate may decrease. If (e.g., when) the ammonium persulfate is included in an amount greater than about 15.0 wt %, it may be difficult to control the etching rate and the anions may increase excessively or substantially, which may lower the etching uniformity of a multi-layer film.

The inorganic acid may be an auxiliary oxidizing agent for etching. The inorganic acid may include nitric acid (HNO₃), sulfuric acid (H₂SO₄), phosphoric acid (H₃PO₄), phosphorous acid (H₃PO₃), p-toluenesulfonic acid (CH₃C₆H₄SO₃), chloric acid (HClO₃), or a (e.g., any suitable) combination thereof. In one or more embodiments, the inorganic acid may be nitric acid.

The inorganic acid may be included in an amount range of about 0.1 wt % to about 5.0 wt % based on the total of 100 wt % of the etchant composition. If (e.g., when) the inorganic acid is included in an amount less than about 0.1 wt %, the etching rate may decrease such that residue may occur or defects may occur in the profile. If (e.g., when) the inorganic acid is included in an amount greater than about 5.0 wt %, over-etching may occur or cracks may occur in a photoresist, thereby reducing productivity.

The fluorine-containing ammonium salt may serve a role in dissociating a metal oxide oxidized by an oxidizing agent. For example, it may act as a dissociating agent for titanium (Ti). The fluorine-containing ammonium salt may also have the ability to etch indium oxide and may serve as an etchant for indium oxide, and may remove residues and/or protrusions that may be generated during etching. In one or more embodiments, the fluorine-containing ammonium salt may be ammonium bifluoride.

The fluorine-containing ammonium salt may be included in an amount range of about 0.1 wt % to about 2.0 wt % based on the total of 100 wt % of the etchant composition. In another example, the fluorine-containing ammonium salt may be included in an amount range of about 0.6 wt % to about 1.0 wt %. If (e.g., when) the fluorine-containing ammonium salt is included in an amount less than about 0.1 wt %, the etching rate may decrease such that residue and/or protrusion formation may occur. If (e.g., when) the fluorine-containing ammonium salt is included in an amount greater than about 2.0 wt %, it may damage the lower layer of the substrate, for example, the silicon-based insulation layer.

The tetraalkyl ammonium chloride may increase or improve yield by preventing over-etching of a metal (or reducing a degree or occurrence of over-etching of a metal). Chloride ions of the tetraalkyl ammonium chloride may have an effect of controlling crevice corrosion (or reducing a degree or occurrence of crevice corrosion) between a photoresist and a metal pattern. Chloride ions may bind to a metal on the surface of a metal pattern in a crevice between a photoresist and a metal pattern, thereby preventing penetration of the oxidizing agent (or reducing a degree or occurrence of penetration of the oxidizing agent) in the etchant composition into the crevice and excessive or substantial side etching on the upper portion of a metal pattern. Furthermore, the presence of the tetraalkyl group may prevent a side angle of a metal pattern from becoming excessively or substantially steep (or reduce a degree to or occurrence of which a side angle of a metal pattern becomes excessively or substantially steep) due to the action of chloride ions. By maintaining the side angle of a metal pattern in a range of about 30 degrees to about 55 degrees, a subsequent layer may be satisfactorily or suitably formed on a metal pattern. In one or more embodiments, the tetraalkyl ammonium chloride may include tetramethyl ammonium chloride, tetraethyl ammonium chloride, tetrapropyl ammonium chloride, or a (e.g., any suitable) combination thereof. For example, the tetraalkyl ammonium chloride may be tetramethyl ammonium chloride.

The tetraalkyl ammonium chloride may be included in an amount range of about 0.01 wt % to about 2.0 wt % based on the total of 100 wt % of the etchant composition. For example, the tetraalkyl ammonium chloride may be included in an amount range of about 0.1 wt % to about 1.5 wt %. If (e.g., when) the tetraalkyl ammonium chloride is included in an amount of less than about 0.01 wt %, the etching rate may decrease and residue may be generated. If (e.g., when) the tetraalkyl ammonium chloride is included in an amount of greater than about 2.0 wt %, the etching rate may increase excessively or substantially and the etching uniformity may decrease.

The amino group-containing sulfonic acid may function as a buffer against changes in acidity in the etchant composition according to the number of substrates processed. The amino group-containing sulfonic acid may prevent or reduce variations in the taper angle of a copper pattern according to the number of substrates processed with the etchant composition. In one or more embodiments, the amino group-containing sulfonic acid may include, for example, sulfamic acid, taurine, aminomethanesulfonic acid, 3-amino-1-propanesulfonic acid, or a (e.g., any suitable) combination thereof. In one or more embodiments, the amino group-containing sulfonic acid may be sulfamic acid.

The amino group-containing sulfonic acid may be included in an amount range of about 0.1 wt % to about 3.0 wt % based on the total of 100 wt % of the etchant composition. If (e.g., when) the amino group-containing sulfonic acid is included in an amount less than about 0.1 wt %, the variation in the taper angle may increase as the cumulative number of processed substrates increases. If (e.g., when) the amino group-containing sulfonic acid is included in an amount greater than about 3.0 wt %, the etching rate may decrease, thereby reducing the etching efficiency.

The alkyl group-containing sulfonic acid may assist in lowering the side angle of a metal pattern. By maintaining the side angle of a metal pattern in a range of about 30 degrees to about 55 degrees together with the tetraalkyl ammonium chloride, a subsequent layer may be formed well or suitably on a metal pattern. The alkyl group-containing sulfonic acid may include methanesulfonic acid, ethanesulfonic acid, propanesulfonic acid, or a (e.g., any suitable) combination thereof. In one or more embodiments, the alkyl group-containing sulfonic acid may be methanesulfonic acid.

The alkyl group-containing sulfonic acid may be included in an amount range of about 0.1 wt % to about 5.0 wt % based on the total of 100 wt % of the etchant composition. If (e.g., when) the amount of the alkyl group-containing sulfonic acid is outside the foregoing range, it may be difficult to control the side angle of a metal pattern.

The 4-nitrogen cyclic compound may serve as a corrosion inhibitor that prevents corrosion of copper (or that reduces a degree or occurrence of corrosion of copper). The 4-nitrogen cyclic compound may include a 4-nitrogen azole-based compound. The 4-nitrogen cyclic compound may include, for example, 5-aminotetrazole, 5-methyltetrazole, 1-methyl-5-aminotetrazole, 1-ethyl-5-aminotetrazole, 5-mercapto-1-methyltetrazole, 5-methoxy-1H-tetrazole, 1H-tetrazole, or a (e.g., any suitable) combination thereof.

The 4-nitrogen cyclic compound may be included in an amount range of about 0.1 wt % to about 2.0 wt % based on the total of 100 wt % of the etchant composition. If (e.g., when) the 4-nitrogen cyclic compound is included in an amount of less than about 0.1 wt %, it may become difficult to control the copper etching rate, thereby leading to over-etching and non-uniform (e.g., substantially non-uniform) etching. If (e.g., when) the 4-nitrogen cyclic compound is included in an amount of greater than about 2.0 wt %, the etching rate may decrease, thereby reducing etching efficiency.

Furthermore, the etchant composition of the disclosure may control the ratio of etching in the vertical direction to etching in the horizontal direction through chelation of copper ions and control of crevice corrosion of chloride ions. The vertical direction is the direction corresponding to the height of the wiring, and the horizontal direction is the direction normal (e.g., substantially perpendicular) to the vertical direction. If (e.g., when) the etching ratio in the vertical direction is high, the side angle of the wiring approaches vertical. The side angle of the wiring refers to the angle formed between the side of the wiring and the bottom of the wiring. If (e.g., when) the side angle of the wiring is less than about 90 degrees, the width of the upper surface of the wiring is narrower than the width of the bottom surface, and if (e.g., when) the side angle of the wiring is more than about 90 degrees, the width of the upper surface of the wiring is wider than the width of the bottom surface. If (e.g., when) the side angle of the wiring is about 90 degrees, the widths of the bottom surface and the upper surface of the wiring may be substantially the same. If (e.g., when) the side angle of the wiring is vertical, the area of the wiring cross-section is large at the desired or suitable scale, which reduce resistance, but it may be difficult to perform a subsequent thin-film deposition process that conforms to the wiring. In contrast, if (e.g., when) the side angle of the wiring is low, for example, less than about 30 degrees, the wiring cross-section becomes closer to a triangle, which increases resistance and may cause the wiring to break at vulnerable points. Therefore, it is desirable for the wiring to have an appropriate or suitable side angle. Furthermore, the etchant composition of the disclosure may improve the ratio of etching in the vertical direction to etching in the horizontal direction, allowing the wiring to have a side angle range of about 30 degrees to about 55 degrees.

In one or more embodiments, the etchant composition may be a composition to etch a metal film, a metal oxide film, a metal nitride film, or a (e.g., any suitable) combination thereof. In one or more embodiments, the etchant composition may be a composition to etch a metal film and a metal oxide film.

For example, the etchant composition may etch a multi-layer film including a metal film and a metal oxide film.

For example, the metal film may include copper, titanium, a titanium alloy, or a (e.g., any suitable) combination thereof, and the titanium alloy may include: titanium; and molybdenum (Mo), tantalum (Ta), chromium (Cr), nickel (Ni), neodymium (Nd), or a (e.g., any suitable) combination thereof.

For example, the metal film may include a first metal film and a second metal film, wherein the first metal film may include titanium or a titanium alloy, wherein the titanium alloy may include: titanium; and Mo, Ta, Cr, Ni, Nd, or a (e.g., any suitable) combination thereof, and the second metal film may include copper.

For example, the metal oxide film may include an oxide of indium (In), tin (Sn), gallium (Ga), zinc (Zn), or any suitable combination thereof. In another example, the metal oxide film may include an oxide of: In; and Sn, Ga, Zn, or a (e.g., any suitable) combination thereof. For example, the metal oxide film may be an oxide of In and Sn (for example, ITO).

For example, the first metal film may include titanium, the second metal film may include copper, and the metal oxide film may include ITO, but embodiments of the present disclosure are not limited thereto.

In one or more embodiments, a metal layer may be patterned utilizing the etchant composition according to the present disclosure.

### Metal Layer Patterning (e.g., Patterning Process)

A method of patterning a metal layer with the etchant composition as described in one or more embodiments will be described herein in more detail.

A method of patterning a metal layer according to one or more embodiments may include:
providing a substrate;
forming a metal layer on the substrate;
forming a photoresist pattern on the metal layer; and
etching the metal layer with the etchant composition as described in one or more embodiments.

The metal layer may be a single layer or a multi-layer. In one or more embodiments, the metal layer may be a multi-layer. For example, the metal layer may include (e.g., consist of) a layer including (e.g., consisting of) a metal, a layer consisting of a metal oxide, a layer including (e.g., consisting of) a metal nitride, or a (e.g., any suitable) combination thereof.

The metal may include copper, titanium, a titanium alloy, or a (e.g., any suitable) combination thereof, and the titanium alloy may include: titanium; and Mo, Ta, Cr, Ni, Nd, or a (e.g., any suitable) combination thereof.

The metal oxide may include an oxide of In, Sn, Ga, Zn, or a (e.g., any suitable) combination thereof. For example, the metal oxide may be indium tin oxide.

The metal nitride may include titanium nitride, tantalum nitride, or a (e.g., any suitable) combination thereof. For example, the metal nitride may be titanium nitride.

In one or more embodiments, the metal layer may include a first metal layer and a second metal layer. The first metal layer may include titanium or a titanium alloy, and the second metal layer may include copper.

In one or more embodiments, the metal layer may further include a metal oxide layer over the second metal layer. For example, the metal oxide layer may be indium tin oxide.

### Production of Display Device

In one or more embodiments, a display device may be produced or manufactured utilizing the etchant composition according to one or more embodiments.

A display device according to one or more embodiments may include: a thin-film transistor including a semiconductor layer, a gate electrode, and a source/drain electrode; and a light-emitting element electrically connected to the source/drain electrode. In one or more embodiments, the display device may further include a bottom metal layer beneath the semiconductor layer. The bottom metal layer may be connected to the source/drain electrode. In one or more embodiments, the light-emitting element may be an organic light-emitting element or a quantum dot light-emitting element.

A method of producing or manufacturing the display device according to one or more embodiments may include:
providing a substrate;
forming a metal layer on the substrate;
forming a photoresist pattern on the metal layer; and
etching the metal layer with the etchant composition as described in one or more embodiments to form a metal layer pattern (e.g., a patterned metal layer),
wherein the metal layer pattern may constitute a gate electrode, a source/drain electrode, or a bottom metal layer of the display device.

The metal layer refers to the metal layer as described herein in the method of patterning a metal layer.

### Display Device

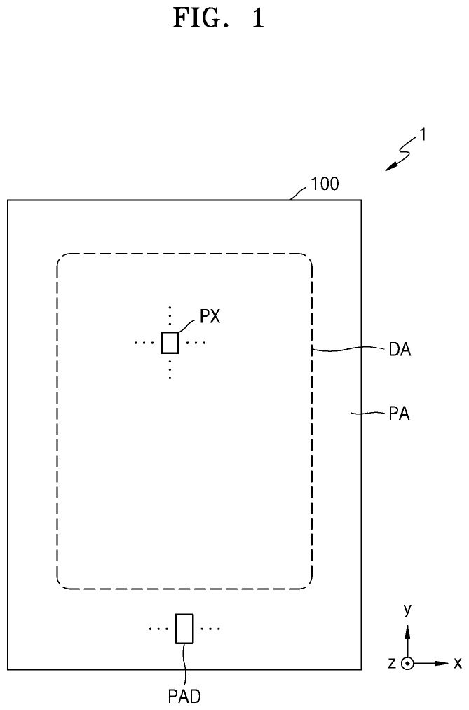

FIG. 1 is a plan view schematically illustrating a display device according to one or more embodiments.

Referring to FIG. 1, a display device 1 may include a display area DA that displays an image and a peripheral area PA around the display area DA. The display device 1 may be to provide an image to the outside using light emitted from a display area DA.

In the display area DA, pixels PX provided with one or more suitable display elements, such as organic light-emitting diodes (OLEDs), may be arranged. The pixel PX may be provided in a plurality, and the plurality of pixels PX may be arranged in one or more suitable forms, such as a stripe arrangement structure, a PENTILE® arrangement structure (e.g., an RGBG matrix, an RGBG structure, or an RGBG matrix structure), a mosaic arrangement structure, and/or the like, to implement an image. PENTILE® is a duly registered trademark of Samsung Display Co., Ltd.

If (e.g., when) viewing the display area DA in a plan view, the display area DA may be provided in a rectangular shape (e.g., a substantially rectangular shape) as illustrated in FIG. 1. In one or more embodiments, the display area DA may be provided in a polygonal shape (e.g., a substantially polygonal shape), such as a triangular shape (e.g., a substantially triangular shape), a pentagonal shape (e.g., a substantially pentagonal shape), or a hexagonal shape (e.g., a substantially hexagonal shape), or as a circular shape (e.g., a substantially circular shape), an oval shape (e.g., a substantially oval shape), an irregular shape, and/or the like.

The peripheral area PA may be an area around the display area DA and may be an area where no image is displayed. The peripheral area PA may fully or partially be around (e.g., surround) the display area DA. The peripheral area PA may contain one or more suitable wirings that transmit electrical signals to be applied to the display area DA, and a pad portion PAD on which a printed circuit board or driver IC chip may be attached.

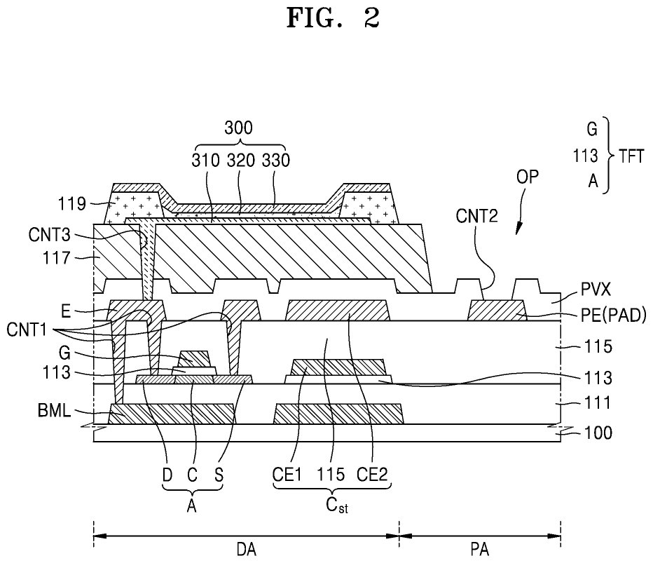

FIG. 2 is a cross-sectional view schematically illustrating a portion of the display device of FIG. 1.

Referring to FIG. 2, a display device according to one or more embodiments may include a thin-film transistor TFT arranged on a substrate 100 corresponding to the display area DA and a pad portion PAD arranged on the substrate 100 corresponding to a peripheral area PA.

The display device 1 may include a planarization layer 117 as an insulation (e.g., electrical insulation) layer arranged on a thin-film transistor TFT and exposing the pad portion PAD, and may include a pixel-defining layer 119 arranged on the planarization layer 117.

The substrate 100 may include (e.g., consist of) one or more suitable materials, such as glass, metal, and plastic. In one or more embodiments, the substrate 100 may include a flexible material. Herein, flexible material refers to a material that may be easily bent, curved, folded, or rolled. The flexible substrate 100 may include (e.g., consist of) ultra-thin glass, metal, and/or plastic.

The buffer layer 111 may be to reduce or block the infiltration of debris, moisture, and/or foreign air from a lower portion of the substrate 100, and may be to provide a flat surface (e.g., a substantially flat surface) on the substrate 100. The buffer layer 111 may include an inorganic material, such as an oxide or nitride, an organic material or an organic-inorganic composite, and may include a single-layer structure or a multi-layer structure of inorganic material and/or organic material.

A barrier layer may be further included between the substrate 100 and the buffer layer 111. The barrier layer may be to serve a role in preventing or minimizing the penetration of impurities (or reducing a degree or occurrence of the penetration of impurities) from the substrate 100, and/or the like, into a semiconductor layer A. The barrier layer may include an inorganic material, such as an oxide or nitride, an organic material or an organic-inorganic composite, and may include a single-layer structure or a multi-layer structure of inorganic material and/or organic material.

A semiconductor layer A may be arranged on the buffer layer 111. In one or more embodiments, the semiconductor layer A may include an oxide semiconductor material. The semiconductor layer A may include, for example, an oxide of at least one material selected from the group consisting of indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn).

For example, the semiconductor layer A may be an indium tin zinc oxide (InSnZnO or ITZO) semiconductor layer, an indium gallium zinc oxide (InGaZnO or IGZO) semiconductor layer, and/or the like. Because oxide semiconductors have a wide band gap (about 3.1 eV), high carrier mobility, and low leakage current, even if (e.g., when) the driving time is long, the voltage drop may not be large, and there is an advantage or benefit in that the luminance change due to the voltage drop may not be large even if (e.g., when) driving at low frequencies.

The semiconductor layer A may include a channel area C, and a source area S and a drain area D arranged on one side and the other side of the channel area C, respectively. The semiconductor layer A may include (e.g., consist of) a single layer or multiple layers.

A bottom metal layer BML may be arranged between the substrate 100 and the buffer layer 111. The bottom metal layer BML may be arranged to overlap the channel area C of the semiconductor layer A. The bottom metal layer BML may include a conductive (e.g., electrically conductive) material including copper (Cu), titanium (Ti), molybdenum (Mo), aluminum (Al), and/or the like and may be formed as a multi-layer or a single layer including the materials as described in one or more embodiments. In one or more embodiments, the bottom metal layer BML may be formed or composed of a bilayer structure of Ti/Cu.

The bottom metal layer BML may be arranged to overlap the semiconductor layer A including an oxide semiconductor material. Because the semiconductor layer A including the oxide semiconductor material has a characteristic of being sensitive to light, the bottom metal layer BML may prevent changes (or reduce a degree or occurrence of changes) in the device characteristics of the thin-film transistor TFT including the oxide semiconductor material caused by photocurrent being induced in the semiconductor layer A by external light incident from the substrate 100 side. In one or more embodiments, the bottom metal layer BML may be connected to the drain area D or the source area S. The thin-film transistor TFT may include the semiconductor layer A, a gate insulation layer 113, and a gate electrode G.

A gate insulation layer 113 may be arranged on the semiconductor layer A. The gate insulation layer 113 may include silicon oxide (e.g., SiOₓ, wherein 0<x≤2; e.g., SiO₂), silicon nitride (e.g., SiₓN_{y}, wherein 0<x≤3 and 0<y≤4; e.g., Si₃N₄), silicon oxynitride (e.g., SiₓON_{y}, wherein 0<x≤2 and 0<y≤2; e.g., SiON or Si₂ON₂), aluminum oxide (e.g., AlOₓ, wherein 0<x≤2; e.g., Al₂O₃), titanium oxide (e.g., TiOₓ, wherein 0<x≤2; e.g., TiO₂), tantalum oxide (e.g., TaₓO_{y}, wherein 0<x≤2 and 0<y≤5; e.g., Ta₂O₅), hafnium oxide (e.g., HfOₓ, wherein 0<x≤2; e.g., HfO₂), zinc oxide (e.g., ZnOₓ, wherein 0<x≤2; e.g., ZnO or ZnO₂), and/or the like. The gate insulation layer 113 may be patterned to overlap at least a portion of the semiconductor layer A. For example, the gate insulation layer 113 may be patterned to expose the source area S and the drain area D.

The area where the gate insulation layer 113 and the semiconductor layer A overlap may be understood as the channel area C. The source area S and the drain area D may undergo a conductor-inducing process, such as plasma treatment, during which the portion of the semiconductor layer A that overlaps the gate insulation layer 113 (in other words, the channel area C) comes to have different properties from the source area S and the drain area D.

In one or more embodiments, the gate insulation layer 113 may not be patterned to overlap a portion of the semiconductor layer A, but may be arranged on the entire surface of the substrate 100 to cover the semiconductor layer A. A gate electrode G may be arranged over the gate insulation layer 113 to at least partially overlap the semiconductor layer A. In one or more embodiments, a first electrode CE1 of a storage capacitor Cst may be arranged on the gate insulation layer 113. The gate electrode G and the first electrode CE1 of the storage capacitor Cst may be formed as a single layer or a multi-layer including (e.g., consisting of) copper (Cu), titanium (Ti), molybdenum (Mo), aluminum (Al), platinum (Pt), palladium (Pd), silver (Ag), magnesium (Mg), gold (Au), nickel (Ni), neodymium (Nd), iridium (Ir), chromium (Cr), molybdenum (Mo), tungsten (W), or a (e.g., any suitable) combination thereof. In one or more embodiments, the storage capacitor Cst may include a first electrode CE1 and a second electrode CE2.

The storage capacitor Cst may further include an interlayer insulation layer 115. The interlayer insulation layer 115 may be provided to cover the semiconductor layer A, the gate electrode G, and the first electrode CE1 of the storage capacitor Cst. The interlayer insulation layer 115 may include silicon oxide (e.g., SiOₓ, wherein 0<x≤2; e.g., SiO₂), silicon nitride (e.g., SiₓN_{y}, wherein 0<x≤3 and 0<y≤4; e.g., Si₃N₄), silicon oxynitride (e.g., SiₓON_{y}, wherein 0<x≤2 and 0<y≤2; e.g., SiON or Si₂ON₂), aluminum oxide (e.g., AlOₓ, wherein 0<x≤2; e.g., Al₂O₃), titanium oxide (e.g., TiOₓ, wherein 0<x≤2; e.g., TiO₂), tantalum oxide (e.g., TaₓO_{y}, wherein 0<x≤2 and 0<y≤5; e.g., Ta₂O₅), hafnium oxide (e.g., HfOₓ, wherein 0<x≤2; e.g., HfO₂), zinc oxide (e.g., ZnOₓ, wherein 0<x≤2; e.g., ZnO or ZnO₂), and/or the like.

An electrode layer E, a second electrode CE2 of a storage capacitor Cst, a pad electrode PE, and/or the like may be arranged on the upper portion of the interlayer insulation layer 115. The electrode layer E may include a source electrode, a drain electrode, a data line, and/or the like.

The electrode layer E, the second electrode CE2 of the storage capacitor Cst, and the pad electrode PE may include a conductive (e.g., electrically conductive) material including copper (Cu), titanium (Ti), molybdenum (Mo), aluminum (AI), a conductive (e.g., electrically conductive) metal oxide, and/or the like, and may be formed as a multi-layer or a single layer including the materials as described in one or more embodiments. The conductive metal oxide may be an oxide of indium (In), tin (Sn), gallium (Ga), zinc (Zn), or a (e.g., any suitable) combination thereof. The conductive metal oxide may be indium tin oxide (ITO), indium zinc oxide (IZO), zinc oxide (ZnO), indium oxide (In₂O₃), indium gallium oxide (IGO), aluminum zinc oxide (AZO), or a (e.g., any suitable) combination thereof. In one or more embodiments, the electrode layer E, the second electrode CE2 of the storage capacitor Cst, and the pad electrode PE may be formed or composed of a multi-layer structure of Ti/Cu/ITO.

The electrode layer E may be connected to the source area S or the drain area D of the semiconductor layer A through a contact hole CNT1. Furthermore, the bottom metal layer BML and the source area S or the drain area D of the semiconductor layer A may be connected through a contact hole CNT1 formed in the buffer layer 111 and the interlayer insulation layer 115.

The second electrode CE2 of the storage capacitor Cst may overlap the first electrode CE1 with an interlayer insulation layer 115 therebetween, forming capacitance. In this case, the interlayer insulation layer 115 may be to function as a dielectric layer of the storage capacitor Cst.

The electrode layer E, the second electrode CE2 of the storage capacitor Cst, and the pad electrode PE may be patterned concurrently (e.g., simultaneously).

The electrode layer E, the second electrode CE2 of the storage capacitor Cst, and the pad electrode PE may be covered with an inorganic protective layer PVX. The inorganic protective layer PVX may be an inorganic insulation (e.g., electrical insulation) film including (e.g., consisting of) an inorganic material. Silicon nitride, silicon oxide, silicon oxynitride, and/or the like may be used as the inorganic material. In one or more embodiments, the inorganic protective layer PVX may be a single film or a multi-layer film of silicon nitride (e.g., SiₓN_{y}, wherein 0<x≤3 and 0<y≤4; e.g., Si₃N₄) and silicon oxide (e.g., SiOₓ, wherein 0<x≤2; e.g., SiO₂). The inorganic protective layer PVX may be introduced to cover and protect one or more wirings arranged on the interlayer insulation layer 115.

The inorganic protective layer PVX may include a contact hole CNT2 to connect a thin-film transistor TFT and a pixel electrode 310, and an opening OP exposing a pad portion PAD. As illustrated in FIG. 1, a printed circuit board or a driver IC chip may be attached to the pad portion PAD.

A planarization layer 117 arranged to cover the electrode layer E and the second electrode CE2 of the storage capacitor Cst, and the planarization layer 117 may include a contact hole CNT3 to connect the thin-film transistor TFT and the pixel electrode 310.

The planarization layer 117 may be formed as a single layer or multiple layers of a film including (e.g., consisting of) an organic material and may provide a flat (e.g., substantially flat) upper surface. This planarization layer 117 may include benzocyclobutene (BCB), hexamethyldisiloxane (HMDSO), or a polymer, such as polyimide, polymethylmethacrylate (PMMA), polystyrene (PS), a phenol-based polymer, an acrylic-based polymer, an imide-based polymer, an aryl ether-based polymer, an amide-based polymer, a fluorine-based polymer, a p-xylene-based polymer, a vinyl alcohol-based polymer, or a (e.g., any suitable) combination thereof.

In one or more embodiments, the planarization layer 117 may be arranged to expose at least a portion of the pad portion PAD.

A light-emitting element 300 may be arranged on the planarization layer 117. The light-emitting element 300 may include a pixel electrode 310, an intermediate layer 320 including an emission layer, and a counter electrode 330.

The pixel electrode 310 may be a (semi)light-transmitting electrode or a reflective electrode. In one or more embodiments, the pixel electrode 310 may be provided with a reflective layer formed or composed of Ag, Mg, Al, Pt, Pd, Au, Ni, Nd, Ir, Cr, compounds thereof, and/or the like, and a transparent or semi-transparent electrode layer formed on the reflective layer. The transparent or semi-transparent electrode layer may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO). In one or more embodiments, the pixel electrode 310 may be provided with ITO/Ag/ITO.

A pixel-defining layer 119 may be arranged on the planarization layer 117. The pixel-defining layer 119 may cover an edge of the pixel electrode 310 and may have an opening exposing a portion of the pixel electrode 310. The pixel-defining layer 119 may serve to prevent arc discharge and/or the like from occurring (or to reduce a degree to or occurrence of which arc discharge and/or the like occur) at the edge of the pixel electrode 310, by increasing the distance between the edge of the pixel electrode 310 and the counter electrode 330 on the upper portion of the pixel electrode 310.

The pixel-defining layer 119 may be formed by a method of spin coating and/or the like, utilizing one or more organic insulation (e.g., electrical insulation) materials selected from the group consisting of polyimide, polyamide, an acrylic resin, benzocyclobutene, and a phenolic resin.

The intermediate layer 320 may be arranged between the pixel electrode 310 and the counter electrode 330 within the opening formed or arranged by the pixel-defining layer 119 and may include an emission layer. The emission layer may include an organic material or an inorganic material including a fluorescent material and/or a phosphorescent material that emits red, green, blue, or white light. The organic material may be a low molecular weight organic material and/or a high molecular weight organic material (e.g., a polymeric organic material), and the inorganic material may be a semiconductor quantum dot material.

Functional layers, such as a hole transport layer (HTL), a hole injection layer (HIL), an electron transport layer (ETL), and an electron injection layer (EIL), may optionally be arranged below and above the emission layer.

The counter electrode 330 may be a light-transmitting electrode or a reflective electrode. In one or more embodiments, the counter electrode 330 may be a transparent electrode or a semi-transparent electrode and may be formed or composed of a thin-film of a metal with a low work-function, including Li, Ca, LiF, Al, Ag, Mg, Cu, Pt, Pd, Au, Ni, Nd, Ir, Cr, Mo, Ti, Yb, W, Na, or compounds thereof (e.g., AgLi or AgNa), or multilayer structure materials, such as LiF/Ca (a stacked structure of LiF and Ca) or LiF/AI (a stacked structure of LiF and Al). In one or more embodiments, a transparent (e.g., substantially transparent) conductive (e.g., electrically conductive) oxide (TCO) film, such as ITO, IZO, ZnO, In₂O₃, and/or the like, may be further arranged on the metal thin-film. The counter electrode 330 may be arranged across the display area DA and may be arranged on the intermediate layer 320 and the pixel-defining layer 119. The counter electrode 330 may be integrally formed in a plurality of light-emitting elements 300 and correspond to a plurality of pixel electrodes 310.

Because these light-emitting elements may be easily damaged by moisture, oxygen, and/or the like from the outside, a thin-film encapsulation layer may cover the light-emitting elements, thus protecting the light-emitting elements.

In the display device 1 as described in one or more embodiments, the etchant composition according to one or more embodiments may be utilized if (e.g., when) forming the bottom metal layer BML, the gate electrode G, the electrode layer E, and the pad electrode PE.

Hereinafter, an etchant composition according to one or more embodiments will be described in more detail with reference to examples.

### EXAMPLES

### Preparation of Etchant Composition

### Examples 1 to 7 and Comparative Examples 1 to 7

Etchant compositions according to Examples 1 to 7 and Comparative Examples 1 to 7 were prepared with the compositions as shown in Table 1. In Table 1, wt % refers to weight percent based on the total weight of the etchant composition. In Table 1, if (e.g., when) the total weight of the etchant composition is 100%, the remaining amount corresponds to water (deionized water).

In Table 1, APS is ammonium persulfate, ABF is ammonium bifluoride, HNO₃ is nitric acid, and ATZ is 5-aminotetrazole. TMACl is tetramethyl ammonium chloride, ACl is ammonium chloride, and the alkyl group-containing sulfonic acid is methanesulfonic acid.

TABLE 1

| | | | | | | | | Alkyl | | | |
|---|---|---|---|---|---|---|---|---|---|---|---|
| | | | | | | | | group- | | | |
| | | | | | | | | containing | Sulfamic | Etching | |
| | APS | ABF | HNO₃ | ATZ | TMACl | ACl | NaCl | sulfonic | acid | amount | Taper |
| | (wt %) | (wt %) | (wt %) | (wt %) | (wt %) | (wt %) | (wt %) | acid(wt %) | (wt %) | value | angle |
| Example 1 | 7 | 0.6 | 3.5 | 1.0 | 0.9 | — | — | 0.6 | 2.0 | 1.1 | OK |
| Example 2 | 8 | 0.7 | 3.0 | 1.0 | 1.0 | — | — | 0.5 | 2.0 | 1.1 | OK |
| Example 3 | 10 | 0.5 | 3.2 | 0.9 | 0.7 | — | — | 0.7 | 1.5 | 1.0 | OK |
| Example 4 | 11 | 0.4 | 3.0 | 1.1 | 1.3 | — | — | 0.8 | 1.3 | 0.9 | OK |
| Example 5 | 13 | 0.5 | 2.8 | 1.2 | 0.8 | — | — | 0.2 | 1.0 | 1.1 | OK |
| Example 6 | 9 | 0.6 | 3.7 | 0.9 | 1.1 | — | — | 0.4 | 2.0 | 1.0 | OK |
| Example 7 | 12 | 0.6 | 3.0 | 1.0 | 1.2 | — | — | 0.5 | 1.5 | 0.9 | OK |
| Comparative | 9 | 0.5 | 3.2 | 1.0 | 0.9 | 0.5 | — | 0.4 | 2.0 | 1.1 | NG |
| Example 1 | | | | | | | | | | | |
| Comparative | 10 | 0.8 | 3.0 | 1.2 | — | — | — | 0.3 | 2.0 | 2.6 | OK |
| Example 2 | | | | | | | | | | | |
| Comparative | 8 | 0.7 | 3.5 | 1.1 | — | 1.2 | — | 0.5 | 2.0 | 1.1 | NG |
| Example 3 | | | | | | | | | | | |
| Comparative | 11 | 0.6 | 3.0 | 1.0 | — | — | 0.8 | 0.7 | 1.5 | 1.3 | NG |
| Example 4 | | | | | | | | | | | |
| Comparative | 13 | 0.6 | 3.0 | 0.9 | 0.6 | — | 0.6 | 1.0 | 1.3 | 1.2 | NG |
| Example 5 | | | | | | | | | | | |
| Comparative | 10 | 0.7 | 3.2 | 1.2 | 0.3 | 0.3 | 0.3 | 0.8 | 1.5 | 1.4 | OK |
| Example 6 | | | | | | | | | | | |
| Comparative | 12 | 0.7 | 3.2 | 1.1 | 1.2 | 1.2 | 1.2 | 0.6 | 2.0 | 0.8 | NG |
| Example 7 | | | | | | | | | | | |

### Evaluation Example

### (1) Production of Test Substrate 1 (Including Ti/Cu)

A film of Ti (200 Å)/Cu (6000 Å) was deposited on a glass substrate, and a photoresist was patterned on the film to produce an etching test substrate 1 (Sample 1). At this time, the width of the photoresist pattern was 20 μm, and the spacing between photoresist patterns was 5 μm. A plurality of the etching test substrates were produced to evaluate each of the etchant compositions of Examples 1 to 7 and Comparative Examples 1 to 7.

### (2) Production of Test Substrate 2 (Including Ti/Cu/ITO)

A film of Ti (200 Å)/Cu (6000 Å)/ITO (550 Å) was deposited on a glass substrate, and a photoresist was patterned on the film to produce an etching test substrate 2 (Sample 2). At this time, the width of the photoresist pattern was 20 μm, and the spacing between photoresist patterns was 8 μm. A plurality of the above test substrates were produced to evaluate each of the etchant compositions of Examples 1 to 7 and Comparative Examples 1 to 7.

### (3) Etching Test Substrate

For each of the etchant compositions of Examples 1 to 7 and Comparative Examples 1 to 7, an etching test was performed by etching the produced test substrates 1 and 2. The etchant compositions were introduced in a spray-type (kind) etching experiment equipment (ETCHER (TFT), SEMES), the temperature was set to about 28° C., followed by etching of the etching test substrates. Endpoint detection (EPD) was determined by detecting the moment if (e.g., when) copper etching was completed and the underlying Ti layer was exposed, using the color change of the test substrate as an indicator. Based on the etching time taken to reach the EPD, a 100% over-etching time was applied to the test substrates. In other words, the etching time was until 100% over etch based on the end point detection (EPD).

### (4) Evaluation of Etching Profile

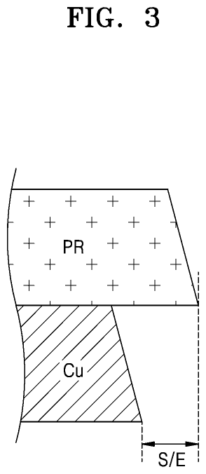

A cross-section of the test substrate etched utilizing the etchant composition was observed using a scanning electron microscope (SEM) to measure a side etching amount S/E indicating the degree of side etching. FIG. 3 is a schematic diagram to illustrate a method of measuring side etching. Referring to FIG. 3, side etching amount S/E represents a distance between the lower end of the etched photoresist (PR) pattern and the lower end of the etched copper (Cu) pattern. The thin metal layer above and/or below the copper pattern is not provided in FIG. 3.

The etching results of the test substrates 1 and 2 utilizing the etchant compositions of Examples 1 to 7 and Comparative Examples 1 to 7 are shown in Table 1.

In Table 1, the etching amount value is defined by the following equation (1) in the present disclosure, and it was evaluated for the Ti/Cu bilayer-containing test substrate.

$$etching amount value = \frac{S}{T} \qquad ( 1 )$$

In equation (1), “S” represents the side etching amount (S/E) of the copper metal layer, and “T” represents the thickness of the etched copper metal layer. The thickness of Ti is much smaller than that of Cu, so it is not included in the calculation of the etching amount value.

In Table 1, the taper angle refers to the angle between the side of the metal pattern and the bottom of the metal pattern, and it was evaluated for a Ti/Cu/ITO trilayer test substrate.

In the evaluation examples in the present disclosure, the Ti/Cu bilayer test substrate has pattern widths and spacings applied to devices with a resolution of approximately 220 PPI, and the Ti/Cu/ITO trilayer test substrate has pattern widths and spacings applied to devices with a resolution of approximately 110 PPI. Because there are differences in the material being etched and the size of the formed patterns between the Ti/Cu pattern and the Ti/Cu/ITO pattern, it is generally common to use different etchant compositions suitable for each in order to form good or suitable patterns. However, if (e.g., when) etching both (e.g., simultaneously) Ti/Cu patterns and Ti/CU/ITO patterns with substantially the same etching equipment, utilizing different etchant compositions may complicate the process, as the etchant composition may need to be changed for each process, leading to increased process complexity and cost. Therefore, if (e.g., when) substantially the same etchant composition is applied for both (e.g., simultaneously) Ti/Cu and Ti/Cu/ITO pattering (e.g., etching processes or patterning processes), it may be highly advantageous or beneficial in terms of process time and cost.

In patterned Ti/Cu bilayer structures applied to higher resolutions, it may be advantageous or beneficial to have an etching amount value within an appropriate or suitable range, while in Ti/Cu/ITO trilayer patterning applied to lower resolutions, it may be advantageous or beneficial to have a taper angle within an appropriate or suitable range.

In the evaluation example of Ti/Cu bilayer patterns, it is preferable or desirable for the etching amount value (S/T) to be in the range of about 0.9 to about 1.1. If (e.g., when) the etching amount value is greater than the maximum value of this range, the metal pattern size may decrease, leading to increased resistance. If (e.g., when) the etching amount value is smaller than the minimum value of this range, short circuits may occur between metal patterns. If (e.g., when) the etching amount value in Ti/Cu bilayer patterns is within this range, the resistance of the metal pattern remains within the desired or suitable range, and patterning may be achieved without short circuits. Therefore, Ti/Cu bilayer patterns with this etching amount value range may be favorably applied in TFT wiring.

In the evaluation example of Ti/CU/ITO trilayer patterns, it is preferable or desirable for the taper angle to be in the range of about 30° to about 55°. In Table 1, the taper angle of the Ti/CU/ITO trilayer pattern that falls within this range is marked as “OK.” If (e.g., when) the taper angle of the Ti/CU/ITO trilayer pattern is smaller than the minimum value of this range, the cross-sectional area of the metal pattern may decrease, leading to increased resistance. If (e.g., when) the taper angle is higher than this range, the metal pattern profile may be good or suitable, but the steep angle between the top and side of the metal pattern may lead to poor coverage of the interlayer insulating layer on the metal pattern. If (e.g., when) the taper angle of the Ti/CU/ITO trilayer pattern is within this range, resistance of the metal pattern may remain within the desired or suitable range, and the slope between the top and side of the metal pattern may be gentle, allowing the interlayer insulating layer to cover the metal pattern effectively.

Referring to Table 1, the etching amount values of the Ti/Cu bilayer patterns etched utilizing the etchant compositions of Examples 1 to 7 all fall within the range of 0.9 to 1.1, and the taper angles of the Ti/CU/ITO trilayer patterns etched utilizing substantially the same etchant compositions fall within the range of 30° to 55°, and thus the etchant compositions were all marked as “OK.” Therefore, it was confirmed that the etchant compositions of Examples 1 to 7 may be applied to both (e.g., simultaneously) Ti/Cu bilayer pattern formation (e.g., patterning) and Ti/Cu/ITO trilayer pattern formation (e.g., patterning).

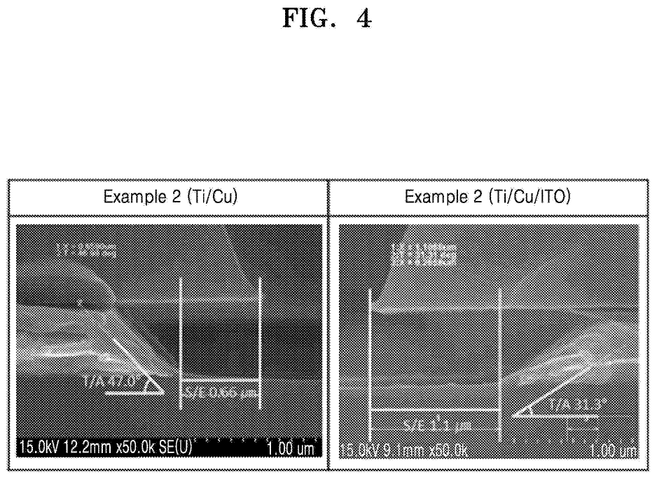

FIG. 4 is cross-sectional SEM images of test substrates 1 (Ti/Cu) and 2 (Ti/Cu/ITO) etched utilizing the etchant composition of Example 2. Referring to FIG. 4, if (e.g., when) the Ti/Cu bilayer was patterned utilizing the etchant composition of Example 2, the side etching amount (S/E) was 0.66 μm, and the thickness (T) of the copper metal layer was 0.6 μm, such that the etching amount value (S/T) was calculated as 0.66 μm/0.6 μm=1.1. When the Ti/Cu/ITO trilayer was patterned using substantially the same etchant composition of Example 2, the taper angle was found to be 31.3°. Therefore, the etchant composition of Example 2 may be applied to both (e.g., simultaneously) Ti/Cu bilayer pattern formation and Ti/Cu/ITO trilayer pattern formation.

In contrast, when the Ti/Cu bilayer and Ti/Cu/ITO trilayer were etched utilizing the etchant compositions of Comparative Examples 1 to 7, one or two of the etching amount value of the Ti/Cu bilayer pattern and the taper angle of the Ti/Cu/ITO trilayer pattern was outside the acceptable range. For example, for Comparative Examples 1 and 3, the etching amount value of the Ti/Cu bilayer pattern is acceptable, but the taper angle of the Ti/Cu/ITO trilayer pattern falls outside the acceptable range. For Comparative Examples 2 and 6, the taper angle of the Ti/CU/ITO trilayer pattern is within the acceptable range, but the etching amount value of the Ti/Cu bilayer pattern falls outside the acceptable range. Also, for Comparative Examples 4, 5, and 7, both (e.g., simultaneously) the etching amount value of the Ti/Cu bilayer pattern and the taper angle of the Ti/Cu/ITO trilayer pattern fall outside the acceptable ranges.

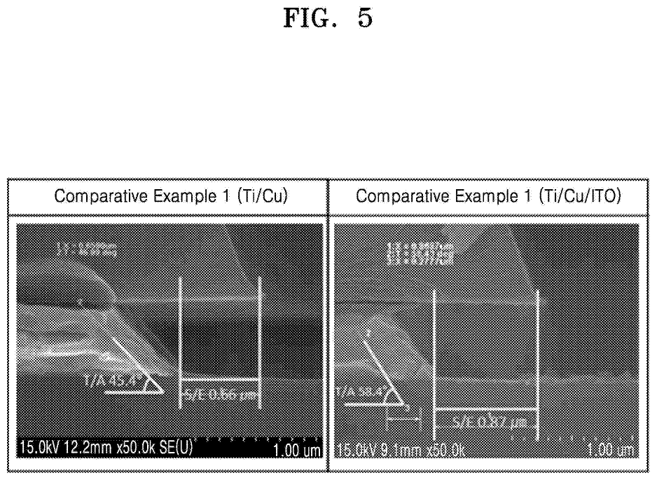

FIG. 5 is cross-sectional SEM images of test substrates 1 (Ti/Cu) and 2 (Ti/Cu/ITO) etched utilizing the etchant composition of Comparative Example 1. Referring to FIG. 5, when the Ti/Cu bilayer was patterned utilizing the etchant composition of Comparative Example 1, the side etching amount (S/E) was 0.66 μm, and the thickness (T) of the copper metal layer was 0.6 μm, and thus, the etching amount value (S/T) was calculated as 0.66 μm/0.6 μm=1.1. When the Ti/Cu/ITO trilayer was patterned utilizing substantially the same etchant composition of Comparative Example 1, the taper angle was found to be 58.4°. Therefore, the etchant composition of Comparative Example 1 satisfies the acceptable range for the etching amount value in Ti/Cu bilayer pattern formation, but the taper angle for Ti/Cu/ITO trilayer pattern formation exceeds the desired or required range.

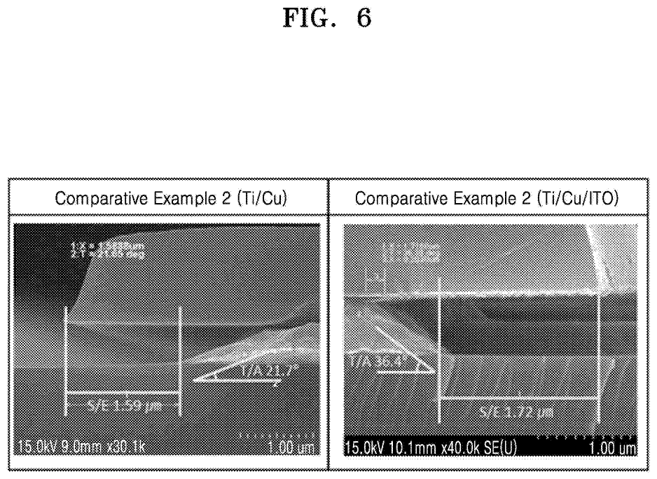

FIG. 6 is cross-sectional SEM images of test substrates 1 (Ti/Cu) and 2 (Ti/Cu/ITO) etched utilizing the etchant composition of Comparative Example 2. Referring to FIG. 6, when the Ti/Cu bilayer was patterned utilizing the etchant composition of Comparative Example 2, the side etching amount (S/E) was 1.59 μm, and the thickness (T) of the copper metal layer was 0.6 μm, and thus, the etching amount value (S/T) was calculated as 1.59 μm/0.6 μm=2.65. When the Ti/CU/ITO trilayer was patterned utilizing substantially the same etchant composition of Comparative Example 2, the taper angle was found to be 36.4°. Therefore, the etchant composition of Comparative Example 2 satisfies the taper angle range for Ti/Cu/ITO trilayer pattern formation, but the etching amount value for Ti/Cu bilayer pattern formation exceeds the desired or required range.

The etchant composition as described in one or more embodiments may etch a metal multilayer film while controlling the profile of the side etching.

A light-emitting device, a display device, a display apparatus, an electronic device, an electronic apparatus, a device for manufacturing substantially the same and/or any other relevant devices or components according to one or more embodiments of the present disclosure may be implemented by utilizing any suitable hardware, firmware (e.g., an application-specific integrated circuit), software, or a (e.g., any suitable) combination of software, firmware, and hardware. For example, the one or more components of the device may be provided on one integrated circuit (IC) chip or on separate IC chips. Further, the one or more components of the device may be implemented on a flexible printed circuit film, a tape carrier package (TCP), and/or a printed circuit board (PCB), or provided on one substrate. Further, the one or more components of the device may be a process or thread, running on one or more processors, in one or more computing devices, executing computer program instructions and interacting with other system components for performing the one or more functionalities described herein. The computer program instructions may be stored in a memory which may be implemented in a computing device utilizing a standard memory device, such as, for example, a random access memory (RAM). The computer program instructions may also be stored in other non-transitory computer readable media, such as, for example, a CD-ROM, flash drive, and/or the like. Also, a person of skill in the art should recognize that the functionality of one or more computing devices may be combined or integrated into a single computing device, or the functionality of a particular computing device may be distributed across one or more other computing devices without departing from the scope of the present disclosure.

It should be understood that embodiments described herein should be considered in a descriptive sense only and not for purposes of limitation. Descriptions of features or aspects within each embodiment should generally be considered as available for other similar features or aspects in other embodiments. While the subject matter of the present disclosure has been described with reference to the drawings, it will be understood by those of ordinary skill in the art that one or more suitable changes in form and more details may be made therein without departing from the spirit and scope as defined by the following claims and equivalents thereof.

What is claimed is:

1. An etchant composition comprising:
3.0 wt % to 15.0 wt % of ammonium persulfate;
0.1 wt % to 5.0 wt % of an inorganic acid;
0.1 wt % to 2.0 wt % of a fluorine-containing ammonium salt;
0.01 wt % to 2.0 wt % of tetraalkyl ammonium chloride;
0.1 wt % to 3.0 wt % of an amino group-containing sulfonic acid;
0.1 wt % to 5.0 wt % of an alkyl group-containing sulfonic acid;
0.1 wt % to 2.0 wt % of a 4-nitrogen cyclic compound; and
a remainder of water, wherein a total weight of the etchant composition is 100 wt %.

2. The etchant composition as claimed in claim 1, wherein the inorganic acid comprises nitric acid (HNO₃), sulfuric acid (H₂SO₄), phosphoric acid, phosphorous acid, p-toluenesulfonic acid (CH₃C₆H₄SO₃), chloric acid (HClO₃), or a combination thereof.

3. The etchant composition as claimed in claim 1, wherein the inorganic acid is nitric acid.

4. The etchant composition as claimed in claim 1, wherein the fluorine-containing ammonium salt is ammonium bifluoride.

5. The etchant composition as claimed in claim 1, wherein the tetraalkyl ammonium chloride comprises tetramethyl ammonium chloride, tetraethyl ammonium chloride, tetrapropyl ammonium chloride, or a combination thereof.

6. The etchant composition as claimed in claim 1, wherein the tetraalkyl ammonium chloride is tetramethylammonium chloride.

7. The etchant composition as claimed in claim 1, wherein the amino group-containing sulfonic acid comprises sulfamic acid, taurine, aminomethanesulfonic acid, 3-amino-1-propanesulfonic acid, or a combination thereof.

8. The etchant composition as claimed in claim 1, wherein the amino group-containing sulfonic acid is sulfamic acid.

9. The etchant composition as claimed in claim 1, wherein the alkyl group-containing sulfonic acid comprises methanesulfonic acid, ethanesulfonic acid, propanesulfonic acid, or a combination thereof.

10. The etchant composition as claimed in claim 1, wherein the 4-nitrogen cyclic compound comprises 5-aminotetrazole, 5-methyltetrazole, 1-methyl-5-aminotetrazole, 1-ethyl-5-aminotetrazole, 5-mercapto-1-methyltetrazole, 5-methoxy-1H-tetrazole, 1H-tetrazole, or a combination thereof.

11. A method of patterning a metal layer, the method comprising:
providing a substrate;
forming a metal layer on the substrate;
forming a photoresist pattern on the metal layer; and
etching the metal layer with the etchant composition as claimed in claim 1 to form a metal layer pattern.

12. The method as claimed in claim 11, wherein the metal layer is a multi-layer.

13. The method as claimed in claim 11, wherein the metal layer comprises a metal, a metal oxide, a metal nitride, or a combination thereof.

14. The method as claimed in claim 13, wherein the metal comprises copper, titanium, a titanium alloy, or a combination thereof, and
wherein the titanium alloy comprises:
titanium; and
molybdenum (Mo), tantalum (Ta), chromium (Cr), nickel (Ni), neodymium (Nd), or a combination thereof.

15. The method as claimed in claim 13, wherein the metal oxide comprises an oxide of indium (In), tin (Sn), gallium (Ga), zinc (Zn), or a combination thereof.

16. The method as claimed in claim 13, wherein the metal oxide is indium tin oxide.

17. The method as claimed in claim 13, wherein the metal nitride comprises titanium nitride, tantalum nitride, or a combination thereof.

18. The method as claimed in claim 11, wherein the metal layer comprises a first metal layer and a second metal layer, and
wherein the first metal layer comprises titanium or a titanium alloy, the titanium alloy comprising: titanium; and molybdenum (Mo), tantalum (Ta), chromium (Cr), nickel (Ni), neodymium (Nd), or a combination thereof, and
the second metal layer comprises copper.

19. The method as claimed in claim 18, wherein the metal layer further comprises a metal oxide layer on the second metal layer, and
wherein the metal oxide layer comprises indium tin oxide.

20. A method of producing a display device, the method comprising:
providing a substrate;
forming a metal layer on the substrate;
forming a photoresist pattern on the metal layer; and
etching the metal layer with the etchant composition as claimed in claim 1 to form a metal layer pattern,
wherein the display device comprises:
a thin-film transistor comprising a semiconductor layer, a gate electrode, and a source/drain electrode; and
a light-emitting element electrically connected to the source/drain electrode, the metal layer pattern constituting the gate electrode or the source/drain electrode.
